(19) United States
(12) Patent Application Publication
(10) Pub. No.: US 2024/0088243 A1
(43) Pub. Date: Mar. 14, 2024

(54) SEMICONDUCTOR STRUCTURE AND FORMING METHOD THEREOF

(71) Applicant: Semiconductor Manufacturing International (Shanghai) Corporation, Shanghai (CN)

(72) Inventors: Cheng TAN, Shanghai (CN); Wentai WANG, Shanghai (CN); Enning ZHANG, Shanghai (CN); Shiliang JI, Shanghai (CN); Haiyang ZHANG, Shanghai (CN)

(21) Appl. No.: 18/140,068

(22) Filed: Apr. 27, 2023

(30) Foreign Application Priority Data
Apr. 27, 2022 (CN) 202210452396.8

(51) Int. Cl. H01L 29/417; H01L 29/40; H01L 29/423; H01L 29/66

(52) U.S. Cl. CPC H01L 29/41775; H01L 29/401; H01L 29/4232; H01L 29/66545

(57) ABSTRACT

A semiconductor structure includes a substrate that includes a base, a plurality of channel layers on the base, and an isolation layer between each of the channel layers. The semiconductor structure also includes a gate on the substrate, spanning a top and a portion of sidewalls of the channel layers. The semiconductor structure also includes a sidewall structure on sidewalls at two sides of the gate, a source/drain region in the substrate at two sides of the gate and the sidewall structure, a source/drain electrical connection layer on the source/drain region, and an isolation structure between the source/drain electrical connection layer and the gate. The isolation structure includes a cavity, including a first cavity region and a second cavity region located on the first cavity region. A width of the second cavity region is smaller than a width of the first cavity region.

### CROSS-REFERENCE TO RELATED APPLICATION

This application claims priority of Chinese Patent Application No. 202210452396.8, filed on Apr. 27, 2022, the entire content of which is hereby incorporated by reference.

### FIELD OF THE DISCLOSURE

The present disclosure generally relates to the field of semiconductor technology and, more particularly, relates to a semiconductor structure and a forming method thereof.

### BACKGROUND

With an increasing integration level of a semiconductor device, a device size is getting smaller. In a small-sized semiconductor device, each device structure is densely arranged. A distance between metal structures such as metal wires and metal gates may decrease continuously, and parasitic capacitance may increase. Accordingly, resistive-capacitive (RC) delay may be severe, and an operating speed and power consumption of the device may be affected. As such, how to reduce parasitic capacitance between metal structures in a semiconductor device is a hot topic of technical research in the field of semiconductor technology.

Air has an ultra-low dielectric constant and is an ideal low-k dielectric material. In recent years, researchers introduced air spaces into isolation dielectric layers in semiconductor devices to reduce parasitic capacitance between each device structure. When the air space introduced has a large size, reduction of parasitic capacitance may be great.

However, in existing technologies, an air gap with a large size may have a low stability and may be damaged in a subsequent process, and device performance may thus be affected.

### BRIEF SUMMARY OF THE DISCLOSURE

One aspect of the present disclosure includes a semiconductor structure. The semiconductor structure includes a substrate. The substrate includes a base, a plurality of channel layers on the base, and an isolation layer between each of the plurality of channel layers. The semiconductor structure also includes a gate located on the substrate. The gate spans a top and a portion of sidewalls of the plurality of channel layers. The semiconductor structure also includes a sidewall structure located on sidewalls at two sides of the gate, a source/drain region in the substrate located at two sides of the gate and the sidewall structure, a source/drain electrical connection layer located on the source/drain region, and an isolation structure located between the source/drain electrical connection layer and the gate. The isolation structure includes a cavity. The cavity includes a first cavity region and a second cavity region located on the first cavity region. A width of the second cavity region is smaller than a width of the first cavity region.

Optionally, the width of the second cavity region is less than approximately 3 nanometers; and the width of the first cavity region is in a range approximately from 4 nanometers to 8 nanometers.

Optionally, a ratio of a length of the second cavity region to a length of the first cavity region is in a range approximately from 1:3 to 1:1.

Optionally, The isolation structure includes a first isolation layer and a second isolation layer. The first isolation layer and the second isolation layer are located on a sidewall of the source/drain electrical connection layer. A cavity groove exists between the sidewall structure and the first isolation layer. The second isolation layer is located on a portion of a sidewall surface of the cavity groove. The second cavity region is located between the second isolation layers.

Optionally, the source/drain region is located in the substrate at a side of the sidewall structure away from the gate.

Another aspect of the present disclosure includes a method of forming a semiconductor structure. The method includes providing a substrate. The substrate includes a base, a plurality of channel layers on the base, and an isolation layer between each of the plurality of channel layers. The method also includes forming a gate on the substrate, a sidewall structure on sidewalls at two sides of the gate, and a source/drain region in the substrate at two sides of the gate and the sidewall structure. The gate spans a top and a portion of sidewalls of the plurality of channel layers. The method also includes forming a source/drain electrical connection layer on the source/drain region, and forming an isolation structure located between the gate and the source/drain electrical connection layer, and a cavity located in the isolation structure. The cavity includes a first cavity region and a second cavity region located on the first cavity region, and a width of the second cavity region is smaller than a width of the first cavity region width.

Optionally, the isolation structure includes a first isolation layer and a second isolation layer located on a sidewall of the source/drain electrical connection layer. A cavity groove exists between the sidewall structure and the first isolation layer. The second isolation layer is located on a portion of a sidewall surface of the cavity groove, and the second cavity region is located between the second isolation layers.

Optionally, a method of forming the isolation structure includes forming a first sacrificial layer on the sidewall structure and forming the first isolation layer on the first sacrificial layer. The source/drain electrical connection layer is formed after the first isolation layer is formed.

Optionally, the method of forming the isolation structure also includes, after forming the source/drain electrical connection layer, etching back the first sacrificial layer to form a second sacrificial layer and an initial cavity groove, depositing the second isolation layer on a sidewall of the initial cavity groove and forming the second cavity region between the second isolation layers, and, after forming the second isolation layer, removing the second sacrificial layer to form the first cavity region.

Optionally, the first sacrificial layer is made of a material including amorphous silicon.

Optionally, a method of removing the second sacrificial layer includes a dry etching process or a wet etching process.

Optionally, a method of removing the second sacrificial layer includes a Frontier process.

Optionally, the method of forming the isolation structure also includes, after forming the source/drain electrical connection layer, removing the first sacrificial layer to form a cavity groove, depositing an initial second sacrificial layer in the cavity groove, and etching back the initial second sacrificial layer to form a second sacrificial layer. A surface of the second sacrificial layer is lower than a surface of the first sacrificial layer. The method of forming the isolation structure also includes depositing the second isolation layer on a sidewall surface of the cavity groove and forming the second cavity region between the second isolation layers, and, after depositing the second isolation layer, removing the second sacrificial layer to form the first cavity region.

Optionally, the second sacrificial layer is made of a carbon-containing material.

Optionally, a process of removing the second sacrificial layer includes an ashing process.

Optionally, a method of forming the gate, the source/drain region, and the sidewall structure includes forming a dummy gate on the substrate, forming a sidewall structure material layer on a sidewall and a top surface of the dummy gate, forming a source/drain region in the substrate at two sides of the dummy gate, forming a first isolation dielectric layer surrounding the source/drain region and the dummy gate on the substrate, removing the dummy gate to form a gate opening, depositing an initial gate within the gate opening, and planarizing the initial gate and the sidewall structure material layer, to form the gate and the sidewall structure on sidewall surfaces at two sides of the gate.

Optionally, a method of forming the source/drain electrical connection layer includes forming a source/drain via in the first isolation dielectric layer, and forming the source/drain electrical connection layer in the source/drain via.

Optionally, after forming the first isolation dielectric layer and before forming the source/drain via, the method also includes forming a first etch stop layer on the first isolation dielectric layer and forming a second isolation dielectric layer on the first etch stop layer. The source/drain via is also located in the second isolation dielectric layer.

Optionally, the second isolation layer is made of a material including silicon nitride, silicon oxide, or a combination thereof.

Optionally, a method of depositing the second isolation layer includes atomic layer deposition.

Optionally, the sidewall structure is made of a material including silicon nitride.

Optionally, after forming the cavity, the method also includes forming a second etch stop layer on a top of the isolation structure. The second etch stop layer encloses the cavity. The method also includes forming an electrical interconnection layer on the gate and on the source/drain electrical connection layer.

As disclosed, the technical solutions of the present disclosure have the following advantages.

In the method of forming a semiconductor structure provided by the present disclosure, the cavity formed includes a first cavity region and a second cavity region located on the first cavity region, and the width of the second cavity region is smaller than the width of the first cavity region. As such, while retaining the large width of the first cavity region, the width of the second cavity region exposed in a subsequent process may be made small. Accordingly, possibility of the cavity being damaged in the subsequent process may be reduced, and an integrity level of the cavity may be improved. A process window may be increased, process compatibility may be improved, and device performance may be improved.

Further, in the process of forming the cavity, the second sacrificial layer may be formed after the first sacrificial layer is well removed, and the second sacrificial layer may then be removed to form the first cavity region. Since the second sacrificial layer is made of a carbon-containing material, the process of removing the carbon-containing material includes an ashing process. Operation of the ashing process may be simple, and the second sacrificial layer may be well removed. Accordingly, the first cavity region formed may have a good shape.

In the semiconductor structure provided by the present disclosure, the cavity includes a first cavity region and a second cavity region located on the first cavity region. The width of the second cavity region is smaller than the width of the first cavity region. That is, while the first cavity region retains a larger width, the width of the second cavity region exposed in the subsequent process is made smaller. Accordingly, the possibility of the cavity being damaged in the subsequent process may be reduced, and the integrity of the cavity may be improved. As such, process compatibility may be increased, and device performance may be improved.

### BRIEF DESCRIPTION OF THE DRAWINGS

The following drawings are merely example s for illustrative purposes according to various disclosed embodiments and are not intended to limit the scope of the present disclosure.

FIG. 1 illustrates a cross-sectional structural diagram of a semiconductor structure;

FIGS. 2 to 10 illustrate cross-sectional structural diagrams corresponding to certain stages of an exemplary process of forming a semiconductor structure, consistent with the disclosed embodiments of the present disclosure;

FIGS. 11 to 14 illustrate cross-sectional structural diagrams corresponding to certain stages of another exemplary process of forming an isolation structure and a cavity, consistent with the disclosed embodiments of the present disclosure; and

FIG. 15 illustrates a flowchart of an exemplary process of forming a semiconductor structure, consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Reference will now be made in detail to exemplary embodiments of the present disclosure, which are illustrated in the accompanying drawings. Wherever possible, the same reference numbers will be used throughout the drawings to refer to the same or like parts.

in existing technologies, an air gap with a large size may have a low stability and may be damaged in a subsequent process, and device performance may thus be affected.

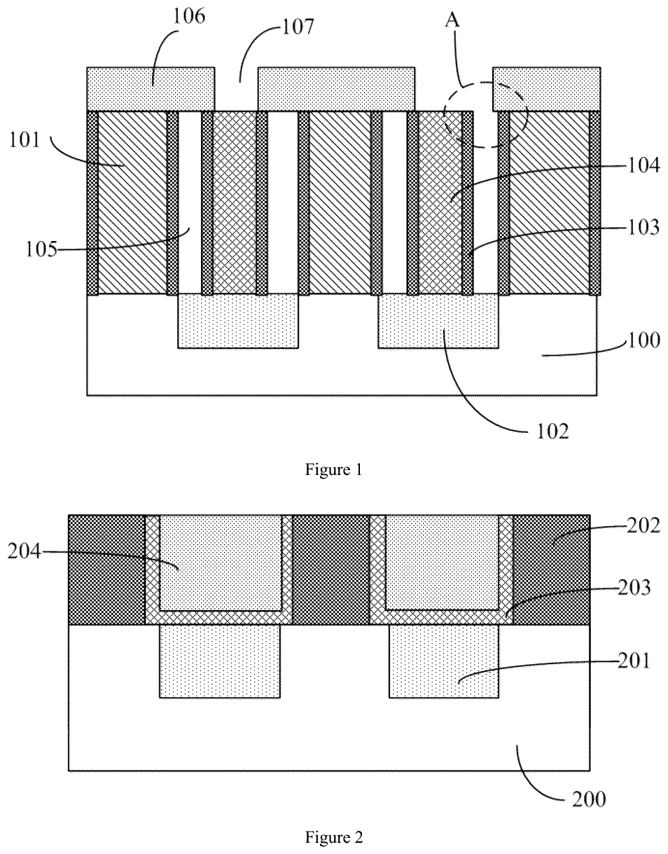

FIG. 1 illustrates a cross-sectional structural diagram of a semiconductor structure. Referring to FIG. 1, the semiconductor structure includes: a substrate 100, a gate 101 located on the substrate 100, a source/drain region 102 located in the substrate 100 at two sides of the gate 101, a source/drain electrical connection layer 104 located on the source/drain region 102, an isolation structure 103 located on sidewalls of the gate 101 and the source/drain electrical connection layer 104, a cavity 105 located in the isolation structure 103, and an interlayer dielectric layer 106 located on the cavity 105, the gate 101 and the source/drain electrical connection layer 104. The interlayer dielectric layer 106 includes a via exposing the source/drain electrical connection layer 104. The via provides a space for subsequent formation of an upper-layer electrical interconnection structure connected to the source/drain electrical connection layer 104.

A top of the cavity 105 is on a same plane as a bottom of the via 107, and the distance between the top of the cavity 105 and the bottom of the via 107 is small. When a size of the cavity 105 is large, a process window of forming the via may be small. During a process of forming the via, the cavity 105 may be broken through, forming a top space A. As a result, the cavity 105 may be destroyed, device performance may be affected, and process compatibility may be reduced.

To solve technical problems described above, the present disclosure provides a method of forming a semiconductor structure. A cavity formed by the method includes a first cavity region and a second cavity region located on the first cavity region. A width of the second cavity region is smaller than a width of the first cavity region. As such, while retaining a large size of the first cavity region, a size of the second cavity region exposed in a subsequent process may be made small. Accordingly, possibility of the cavity being damaged in the subsequent process may be reduced, and an integrity level of the cavity may be improved. A process window may be increased, process compatibility may be improved, and device performance may be improved.

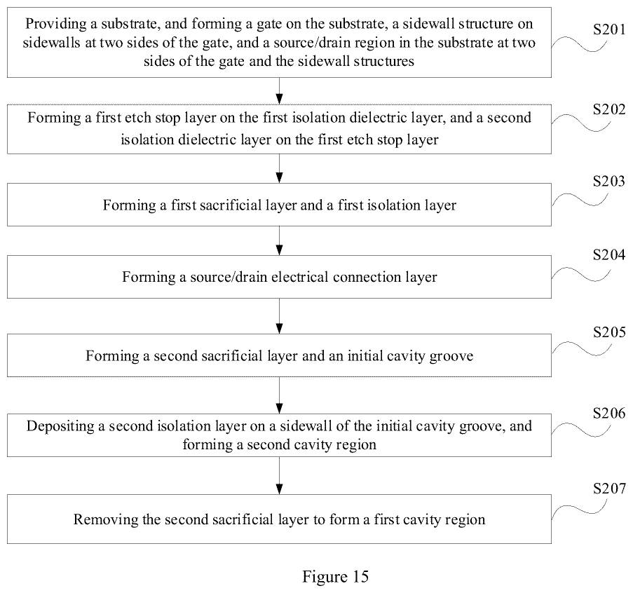

FIG. 15 illustrates a flowchart of an exemplary forming process of a semiconductor structure, consistent with the disclosed embodiments of the present disclosure. FIGS. 2 to 10 illustrate cross-sectional structural diagrams corresponding to certain stages of an exemplary process of forming a semiconductor structure, consistent with the disclosed embodiments of the present disclosure.

As shown in FIG. 15, at the beginning of the forming process, a substrate is provided, followed by forming a gate on the substrate, a sidewall structure on sidewalls at two sides of the gate, and a source/drain region in the substrate at two sides of the gate and the sidewall structures (S201). FIG. 2 illustrates a corresponding semiconductor structure.

Referring to FIG. 2, a substrate 200 is provided, followed by forming a gate 202 on the substrate 200, a sidewall structure 203 on sidewalls at two sides of the gate 202, and a source/drain region 201 in the substrate 200 at two sides of the gate 202 and the sidewall structures 203.

The substrate 200 includes a base (not shown), a plurality of channel layers (not shown) on the base, and an isolation layer (not shown) between each of the plurality of channel layers.

The plurality of channel layers is made of a material including silicon, silicon germanium, silicon carbide, silicon on insulator (SOI), germanium on insulator (GOI), or a combination thereof. Specifically, in one embodiment, the plurality of channel layers is made of a material including silicon.

In one embodiment, the gate 202 spans a top and a part of sidewalls of the plurality of channel layers.

In one embodiment, while forming the gate 202 and the source/drain region 201, the sidewall structure 203 on the surfaces of the gate 202, and a first isolation dielectric layer 204 on the substrate 200 are also formed. The first isolation dielectric layer 204 surrounds the source/drain region 201 and the gate 202. The sidewall structure 203 is configured to protect the gate 202 and control a height of the gate 202. The first isolation dielectric layer 204 operates as an isolation structure between each gate 202.

In one embodiment, a method of forming the gate 202, the source/drain region 201, the sidewall structure 203 and the first isolation dielectric layer 204 includes forming a dummy gate (not shown) on the substrate 200, forming a sidewall structure material layer (not shown) on a sidewall and a top surface of the dummy gate, forming the source/drain region 201 in the substrate 200 at two sides of the dummy gate, forming the first isolation dielectric layer 204 surrounding the source/drain region 201 and the dummy gate on the substrate 200, removing the dummy gate to form a gate opening, depositing an initial gate (not shown) within the gate opening, and planarizing the initial gate and the sidewall structure material layers, to form the gate 202 and the sidewall structures 203 on the sidewall surfaces at two sides of the gate 202.

In one embodiment, the sidewall structure 203 is made of a material including silicon nitride.

In one embodiment, due to uniformity of a process of forming the sidewall structure 203, part of the sidewall structure 203 is located on a surface of the source/drain region 201.

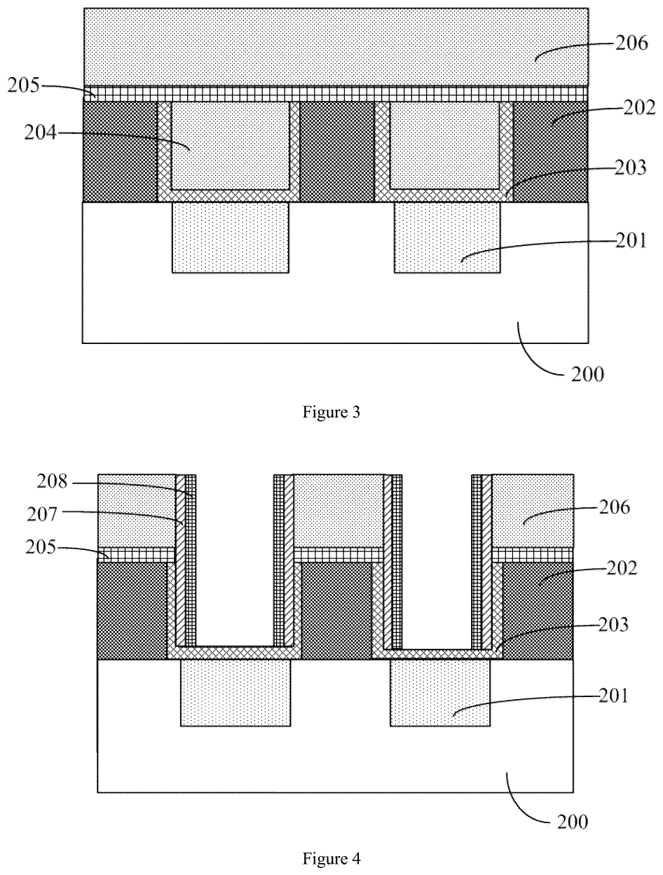

Returning to FIG. 15, after providing the substrate and forming the gate, the sidewall structure and a source/drain region, a first etch stop layer may be formed on the first isolation dielectric layer, and a second isolation dielectric layer may be formed on the first etch stop layer (S202). FIG. 3 illustrates a corresponding semiconductor structure.

Referring to FIG. 3, a first etch stop layer 205 is formed on the first isolation dielectric layer 204, and a second isolation dielectric layer 206 is formed on the first etch stop layer 205.

In one embodiment, during subsequent formation of a source/drain electrical connection layer, the first etch stop layer 205 may be used as an etch stop layer for the formation of the source/drain electrical connection layer, to control a height of the source/drain electrical connection layer.

In one embodiment, due to the second isolation dielectric layer 206, a process window for subsequent formation of the source/drain electrical connection layer may be increased, and morphology of the source/drain electrical connection layer formed may be improved.

Returning to FIG. 15, after forming the first etch stop layer and a second isolation dielectric layer, a first sacrificial layer and a first isolation layer may be formed (S203). FIG. 4 illustrates a corresponding semiconductor structure.

Referring to FIG. 4, the first isolation dielectric layer 204, the first etch stop layer 205 and the second isolation dielectric layer 206 on the source/drain regions 201 are etched, to form a source/drain groove (not shown) between the adjacent gates 202 in the first isolation dielectric layer 204 and the second isolation dielectric layer 206. The source/drain groove exposes a surface of the sidewall structure 203.

The source/drain groove provide a space for the source/drain electrical connection layer, a first sacrificial layer and a first isolation layer subsequently formed.

After forming the source/drain groove, a first sacrificial layer 207 is formed on the sidewall structure 203, and a first isolation layer 208 is formed on the first sacrificial layer 207. The first sacrificial layer 207 may provide a space for a cavity subsequently formed.

Specifically, a method of forming the first sacrificial layer 207 includes depositing a first sacrificial material layer (not shown) on a sidewall surface of the sidewall structure 203 and a surface of the second isolation dielectric layer 206. The method of forming the first sacrificial layer 207 also includes etching back the first sacrificial material layer on a top surface of the second isolation dielectric layer 206 to form the first sacrificial layer 207.

In one embodiment, the first sacrificial layer 207 is made of a material including amorphous silicon. A deposition process of the first sacrificial material layer includes atomic layer deposition.

The first isolation layer 208 is configured to isolate the gate 202 and the source/drain electrical connection layer subsequently formed.

A method of forming the first isolation layer 208 includes depositing a first isolation material layer (not shown) on a sidewall surface of the first sacrificial layer 207 and the surface of the second isolation dielectric layer 206. The method of forming the first isolation layer 208 also includes etching back the first isolation material layer on the top surface of the second isolation dielectric layer 206 to form the first isolation layer 208. The first isolation layer 208 is made of a material including a low-K material. Specifically, the first isolation layer 208 is made of a material including carbon-doped silicon nitride.

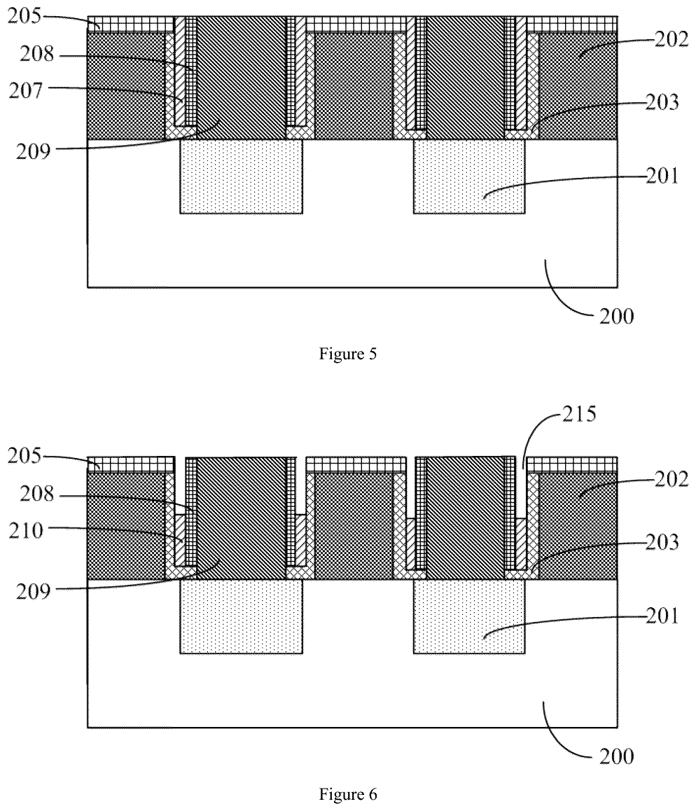

Returning to FIG. 15, after forming the first sacrificial layer and the first isolation layer, a source/drain electrical connection layer may be formed (S204). FIG. 5 illustrates a corresponding semiconductor structure.

Referring to FIG. 5, a source/drain via (not shown) is formed in the first isolation dielectric layer 204 and the second isolation dielectric layer 206, and a source/drain electrical connection layer 209 is formed in the source/drain via.

In one embodiment, a sidewall of the source/drain via is in contact with a surface of the first isolation layer 208. The source/drain via also penetrates the sidewall structure 203 on the source/drain region 201. Accordingly, the source/drain via exposes the surface of the source/drain region 201.

Specifically, a method of forming the source/drain via includes etching the sidewall structure 203 on the source/drain region 201 until the surface of the source/drain region 201 is exposed. Accordingly, the source/drain via, located in the first isolation dielectric layer 204 and the second isolation dielectric layer 206, is formed on the source/drain region 201.

Before the source/drain via on the source/drain region 201 is formed, the source/drain groove in the first isolation dielectric layer 204 and the second isolation dielectric layer 206 on the source/drain region 201 is formed. The first isolation dielectric layer 204 and the second isolation dielectric layer 206 do not need to be etched. The source/drain via exposing the surface of the source and drain region 201 may be formed by only etching the sidewall structure 203 on the source/drain region 201.

A method of forming the source/drain electrical connection layer 209 in the source/drain via includes forming an initial electrical connection layer (not shown) in the source/drain via. The method of forming the source/drain electrical connection layer 209 also includes etching back the initial electrical connection layer and the second isolation dielectric layer 206 until the first etch stop layer 205 is exposed to form the source/drain electrical connection layer 209.

The source/drain electrical connection layer 209 is connected with the source/drain region 201. The source/drain electrical connection layer 209 may be used as an electrical contact between the source/drain region 201 and an electrical interconnection layer subsequently formed on the first isolation dielectric layer 204.

After forming the source/drain electrical connection layer 209, an isolation structure located between the gate 202 and the source/drain electrical connection layer 209, and a cavity located in the isolation structure may be formed. The cavity includes a first cavity region and a second cavity region located on the first cavity region. A width of the second cavity region is smaller than a width of the first cavity region width.

Specifically, the isolation structure includes the first isolation layer 208 and a second isolation layer located on the sidewall of the source/drain electrical connection layer 209. A cavity groove exists between the sidewall structure 203 and the first isolation layer 208. The second isolation layer is located on a part of the sidewall surface of the cavity groove, and the second cavity region is located between the second isolation layers.

FIGS. 6 to 10 illustrate cross-sectional structural diagrams corresponding to certain stages of a process of forming an isolation structure and a cavity in one embodiment.

Returning to FIG. 15, after forming the source/drain electrical connection layer, a second sacrificial layer and an initial cavity groove may be formed (S205). FIG. 6 illustrates a corresponding semiconductor structure.

Referring to FIG. 6, the first sacrificial layer 207 may be etched back to form a second sacrificial layer 210 and an initial cavity groove 215. By etching back the first sacrificial layer 207, the space between the sidewall structure 203 and the first isolation layer 208 is divided into two parts. A second cavity region and a first cavity region with different widths may then be formed in a subsequent process. The initial cavity groove 215 provides a space for the second cavity region subsequently formed, and the second sacrificial layer 210 provides a space for the first cavity region subsequently formed.

Lengths of the initial cavity groove 215 and the second sacrificial layer 210 depend on required lengths of the second cavity region and the first cavity region formed subsequently. In one embodiment, the length of the initial cavity groove 215 is in a range approximately from 50 angstroms to 400 angstroms.

In one embodiment, a method of etching back the first sacrificial layer 207 includes a Frontier process. The Frontier process includes following parameters. Etching gas used includes one or a combination of NF3, H2, Ar and He. A gas flow rate is in a range approximately from 50 sccm to 7000 sccm. Gas dissociation power is in a range approximately from 0 W to 2000 W. Reaction temperature is in a range approximately from 50 degrees Celsius to 150 degrees Celsius. An etching rate is in a range approximately from 10 A/min to 100 A/min. Reaction pressure is in a range approximately from 0.7 Torr to 2 Torr. Reaction time is in a range approximately from 20 seconds to 60 seconds.

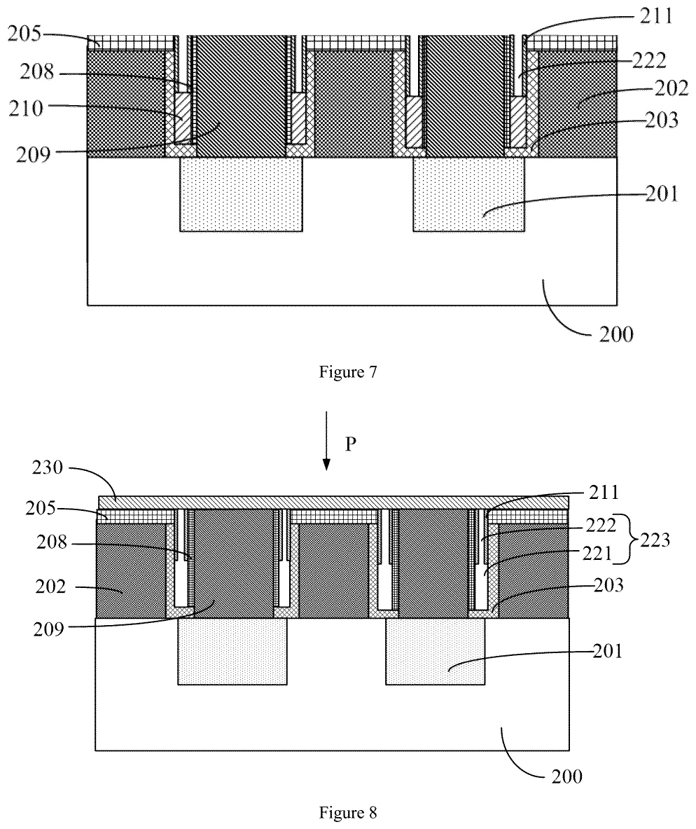

Returning to FIG. 15, after forming the second sacrificial layer and the initial cavity groove, a second isolation layer may be deposited on a sidewall of the initial cavity groove, and a second cavity region may be formed (S206). FIG. 7 illustrates a corresponding semiconductor structure.

Referring to FIG. 7, a second isolation layer 211 is deposited on a sidewall of the initial cavity groove 215. A second cavity region 222 is formed between the second isolation layers 211.

By forming the second isolation layer 211 on the sidewall of the initial cavity groove 215, a width of the initial cavity groove 215 in a direction perpendicular to the sidewall of the gate 202 is reduced. Accordingly, a width of the second cavity region 222 in the direction perpendicular to the sidewall of the gate 202 is smaller than a thickness of the second sacrificial layer 210 in the direction perpendicular to the sidewall of the gate 202. As such, the width of the second cavity region 222 exposed in a subsequent process may be small, and possibility of the cavity being damaged in a subsequent process may be decreased.

The greater the thickness of the second isolation layer 211 is, the greater the decrease of the width of the initial cavity groove 215 in the direction perpendicular to the sidewall of the gate 202 is. The smaller the width of the second cavity region 222 is, the less the possibility of the cavity being damaged in subsequent process is.

In one embodiment, the thickness of the second isolation layer 211 along the direction perpendicular to the sidewall of the gate 202 is in a range approximately from 1 nanometer to 3 nanometers.

In one embodiment, the second isolation layer 211 is made of a material including silicon nitride. Due to presence of silicon nitride, the source/drain electrical connection layer 209 may be protected, and leakage between the source/drain electrical connection layer 209 and the gate 202 may be reduced.

In another embodiment, the second isolation layer 211 is made of a material including silicon oxide. Compared with the second isolation layer made of a material including silicon nitride, since a dielectric constant of silicon oxide is lower, parasitic capacitance between the source/drain electrical connection layer 209 and the gate 202 may be reduced.

In one embodiment, a method of depositing the second isolation layer 211 includes atomic layer deposition. An atomic layer deposition process may have good coverage forming ability, may have strong control over thicknesses and shapes of deposits. Accordingly, the second isolation layer 211 and the second cavity region 222 with good morphology may be formed.

After forming the second isolation layer 211, the second isolation layer 211 on the surface of the first etch stop layer 205 and the source/drain electrical connection layer 209 is etched back, until surfaces of the first etching stop layer 205 and the source/drain electrical connection layer 209 are exposed.

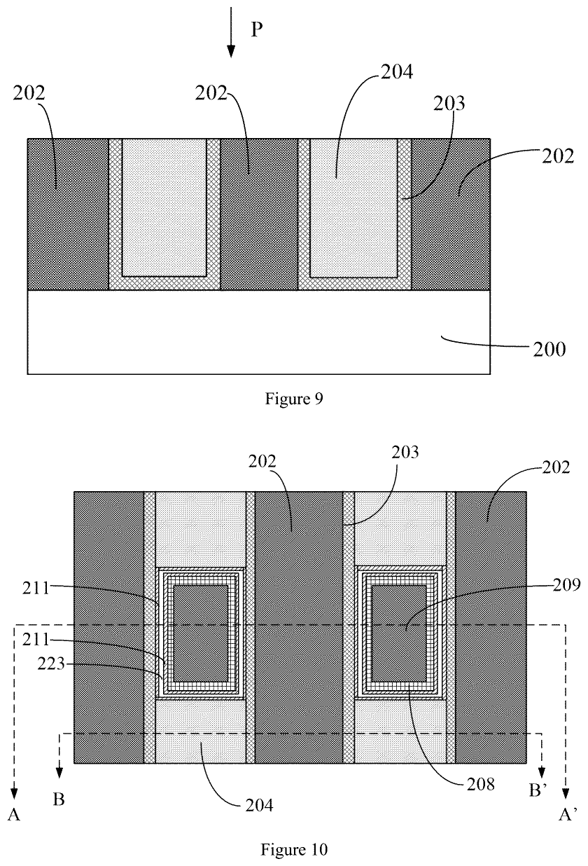

FIG. 8 illustrates a cross-sectional structural diagram along direction AA′ of FIG. 10. FIG. 9 illustrates a cross-sectional structural diagram along direction BB′ of FIG. 10. FIG. 10 illustrates a top view along direction P of FIG. 8 and FIG. 9.

Returning to FIG. 15, after depositing the second isolation layer and forming the second cavity region, the second sacrificial layer may be removed to form a first cavity region (S207). FIGS. 8-10 illustrate a corresponding semiconductor structure.

Referring to FIGS. 8-10, after forming the second isolation layer 211, the second sacrificial layer 210 is removed to form the first cavity region 221. The first cavity region 221 and the second cavity region 222 form a cavity 223.

Returning to FIG. 15, after removing the second sacrificial layer, a second etch stop layer may be formed on top of the isolation structure, and an electrical interconnection layer may be formed on the gate and on the source/drain electrical connection layer. FIGS. 8-10 illustrate a corresponding semiconductor structure.

Referring to FIGS. 8-10, after forming the cavity 223, the method of forming the semiconductor structure also includes forming a second etch stop layer 230 on top of the isolation structure, the second etch stop layer 230 enclosing the cavity 223. The method of forming the semiconductor structure also includes forming an electrical interconnection layer (not shown) located on the gate 202 and on the source/drain electrical connection layer 209.

In one embodiment, the cavity 223 is located between the source/drain electrical connection layer 209 and the gate 202, and air is enclosed in the cavity 223. Since air has a low dielectric constant, the parasitic capacitance between the source/drain electrical connection layer 209 and the gate 202 may be reduced. Accordingly, the resistive-capacitive (RC) delay of the device may be reduced, and the operating speed of the device may be increased.

A width of the second cavity region 222 located on the first cavity region 221 is smaller than a width of the first cavity region 221. Since the second isolation layer 211 is formed on the sidewall of the initial cavity groove 215, the width of the initial cavity groove 215 is decreased. Accordingly, while forming the second cavity region 222 with a smaller width, an original thickness of the second sacrificial layer 210 is retained to form the first cavity region 221. As such, while the first cavity region 221 retains a larger width, the width of the second cavity region 222 exposed in the subsequent formation process of the electrical interconnection layer may be made smaller. The possibility of the cavity 223 being damaged in the subsequent process may be reduced, and the integrity of the cavity 223 may be improved. The process window may be expanded, the process compatibility may be increased, and the device performance may be improved.

When the length of the first cavity region 221 is longer, the effect of the cavity 223 on reducing the parasitic capacitance between the source/drain electrical connection layer 209 and the gate 202 is better. However, since the first cavity region 221 is also closer to a platform of a subsequent process of forming the electrical interconnection layer, the stability of the cavity 223 may be poor, and the cavity 223 may be damaged in the subsequent process.

When the length of the second cavity region 222 is longer, the first cavity region 221 with a larger width is farther away from platform of the subsequent process. Due to the smaller width of the second cavity region 222, the second cavity region 222 is less exposed to the subsequent process of forming the electrical interconnection layer. As a result, the cavity 223 is less likely to be damaged, and the process compatibility may be improved. However, since the first cavity region 221 with a larger width is shorter in length, the overall size of the cavity 223 is smaller. Accordingly, the cavity 223 may have a limited effect on reducing the parasitic capacitance between the source/drain electrical connection layer 209 and the gate 202.

By adjusting a length ratio of the second cavity region 222 to the first cavity region 221, the cavity 223 may be adapted to semiconductor devices with different performance requirements. Accordingly, a semiconductor structure including the cavity 223 may have a wider application range.

In one embodiment, the length ratio of the second cavity region 222 to the first cavity region 221 is in a range approximately from 1:3 to 1:1. Preferably, the length ratio of the second cavity region 222 to the first cavity region 221 is approximately 1:2.

In one embodiment, the width of the second cavity region 222 is less than approximately 3 nanometers, and the width of the first cavity region 221 is in a range approximately from 4 nanometers to 8 nanometers.

In one embodiment, a method of removing the second sacrificial layer 210 includes a dry etching process or a wet etching process. Specifically, the method of removing the second sacrificial layer 210 includes a Frontier process. The Frontier process includes following process parameters. Etching gas used includes one or a combination of NF3, H2, Ar and He. A gas flow rate is in a range approximately from 50 sccm to 7000 sccm. Gas dissociation power is in a range approximately from 0 W to 2000 W. Reaction temperature is in a range approximately from 50 degrees Celsius to 150 degrees Celsius. An etching rate is in a range approximately from 5 A/min to 50 A/min. Reaction pressure is in a range approximately from 0.7 Torr to 2 Torr. Reaction time is in a range approximately from 10 seconds to 30 seconds.

Since the Frontier process may etch a material in a narrow space below 5 angstroms, the second sacrificial layer 210 may be well removed. In addition, the sidewall structure 203 is made of a material including silicon nitride, the second isolation layer 211 is made of a material including silicon nitride, and the first isolation layer 208 is made of a material including carbon-doped silicon nitride. Since the Frontier process has a high etching selectivity ratio for amorphous silicon and silicon nitride, the spacer structure 203, the second isolation layer 211 and the first isolation layer 208 may not be damaged while removing the second sacrificial layer 210.

Since the width of the second cavity region 222 is small, the portion exposed to the process of forming the electrical interconnection layer is small. As such, the damage of the process of forming the electrical interconnection layer to the cavity 223 may be small. Accordingly, in the process of forming the electrical interconnection layer on the gate 202, the electrical interconnection layer may be directly in contact with the surface of the gate 202. An electrical contact layer between the electrical interconnection layer and the gate 202 may not be needed. Accordingly, the electrical connection performance may be improved, and the fabrication process may be simplified.

Referring to FIGS. 9 and 10, the first isolation dielectric layer 204 may be used as an isolation structure between each gate 202. In addition, the first isolation dielectric layer 204 may also provide a space for the formation of the cavity 223 and protect the cavity 223. It should be noted that, for ease of understanding, the second etch stop layer 230 is omitted in FIGS. 9 and 10.

FIGS. 11 to 14 illustrate cross-sectional structural diagrams corresponding to certain stages of another exemplary process of forming an isolation structure and a cavity.

Referring to FIG. 11 based on FIG. 5, after forming the source/drain electrical connection layer, the first sacrificial layer is removed to form a cavity groove 330. The cavity groove 330 provides a space for a cavity formed subsequently.

In one embodiment, a method of removing the first sacrificial layer includes a dry etching process or a wet etching process. Specifically, the method of removing the first sacrificial layer includes a Frontier process. The Frontier process includes following parameters. Etching gas used includes one or a combination of NF3, H2, Ar and He. A gas flow rate is in a range approximately from 50 sccm to 7000 sccm. Gas dissociation power is in a range approximately from 0 W to 2000 W. Reaction temperature is in a range approximately from 50 degrees Celsius to 150 degrees Celsius. An etching rate is in a range approximately 10 A/min to 100 A/min. Reaction pressure is in a range approximately from 0.7 Torr to 2 Torr. Reaction time is in a range approximately from 20 seconds to 60 seconds.

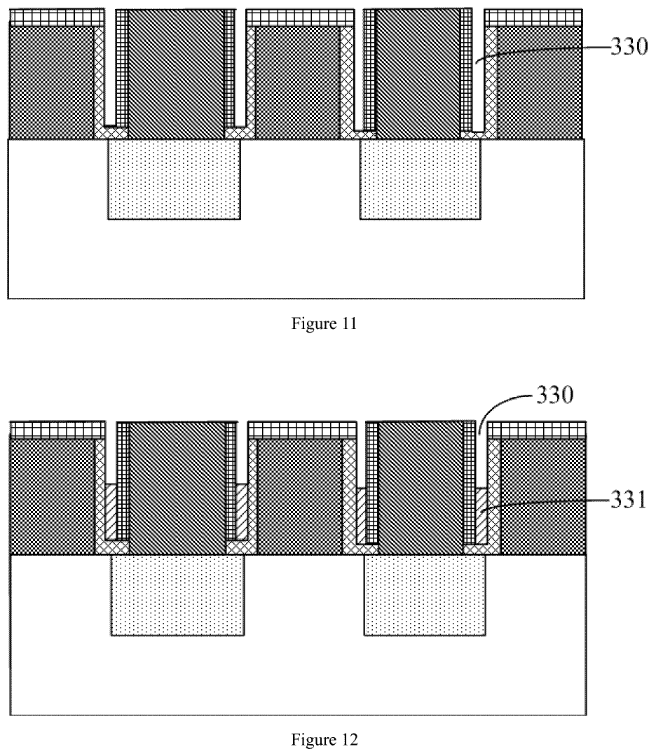

Referring to FIG. 12, an initial second sacrificial layer (not shown) is deposited in the cavity groove 330. The initial second sacrificial layer is then etched back to form a second sacrificial layer 331. A surface of the second sacrificial layer 331 is lower than the surface of the first sacrificial layer.

By forming the second sacrificial layer 331, the space between the sidewall structure and the first isolation layer is divided into two parts, and a second cavity region and a first cavity region with different widths may be formed in a subsequent process. The cavity groove 330 on the second sacrificial layer 331 provides a space for the second cavity region formed subsequently. The second sacrificial layer 331 provides a space for the first cavity region subsequently formed.

The second sacrificial layer 331 is made of a carbon-containing material. The reason why the second sacrificial layer 331 made of a carbon-containing material is used to replace the first sacrificial layer made of amorphous silicon is that, after subsequent formation of the second cavity region with a smaller width, the second sacrificial layer 331 may be better removed to form the first cavity region, and the removal process may be simpler.

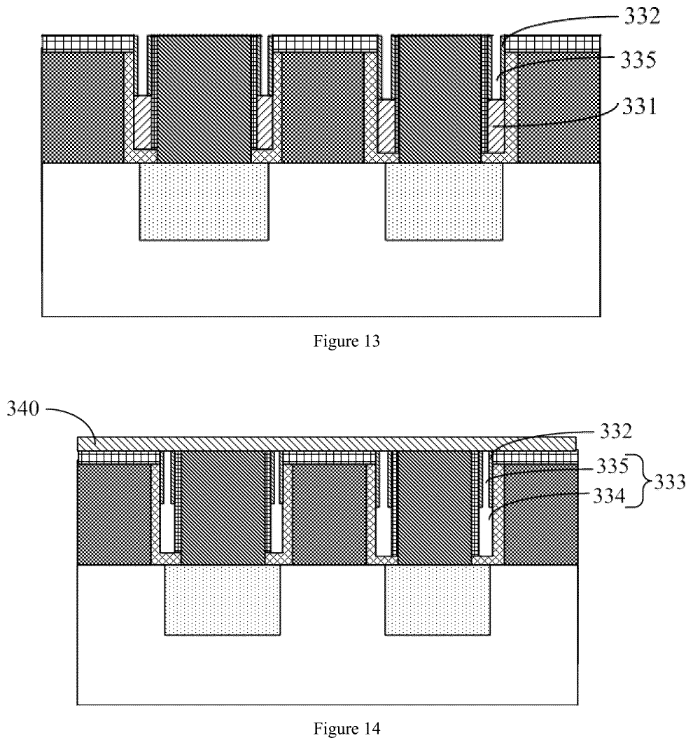

Referring to FIG. 13, a second isolation layer 332 is deposited on the sidewall surface of the cavity groove 330, and a second cavity region 335 is formed between the second isolation layers 332.

By forming the second isolation layer 332 on the sidewall of the cavity groove 330, the width of the cavity groove 330 in the direction perpendicular to the sidewall of the gate is reduced. Accordingly, the width of the second cavity region 335 exposed in the subsequent process is reduced, and the possibility of the cavity being damaged in the subsequent process is reduced.

The material, structure, and formation method of the second isolation layer 332 are consistent with the material, structure and formation method of the second isolation layer 211 in FIG. 7. The present disclosure will not go into details here.

Referring to FIG. 14, after forming the second isolation layer 332, the second sacrificial layer 331 is removed to form a first cavity region 334. The first cavity region 334 and the second cavity region 335 form a cavity 333.

In one embodiment, a process of removing the second sacrificial layer 331 includes an ashing process. Compared with an amorphous silicon material, the carbon-containing material of the second sacrificial layer 331 is easier to be removed, and a removal process is simpler. When the width of the second cavity region 335 is small, the second sacrificial layer 331 made of a carbon-containing material may be removed better and more simply. As such, the first cavity region 335 with a good shape may be formed, and the cavity 333 may have a larger size. Accordingly, the parasitic capacitance may be reduced, and the performance of the device may be improved.

After forming the cavity 333, the method of forming the semiconductor structure also includes forming a second etch stop layer 340 on top of the isolation structure, the second etch stop layer 340 enclosing the cavity 333. The method of forming the semiconductor structure also includes forming an electrical interconnection layer on the gate and on the source/drain electrical connection layer.

The present disclosure also provides a semiconductor structure formed by the method of forming a semiconductor structure provided by the present disclosure. Referring to FIG. 8, the semiconductor structure includes a substrate 200. The substrate 200 includes a base (not shown), a plurality of channel layers (not shown) on the base, and an isolation layer (not shown) between each of the channel layers. The semiconductor structure also includes a gate 202 located on the substrate 200, and the gate 202 spans a top and part of the sidewall of the channel layers. The semiconductor structure also includes a sidewall structure 203 located on the sidewalls at two sides of the gate 202, a source/drain region 201 in the substrate 200 located at two sides of the gate 202 and the sidewall structure 203, a source/drain electrical connection layer 209 located on the source/drain region 201, and an isolation structure (not labeled) located between the source/drain electrical connection layer 209 and the gate 202. The isolation structure includes a cavity 223. The cavity 223 includes a first cavity region 221 and a second cavity region 222 located on the first cavity region 221. A width of the second cavity region 222 is smaller than a width of the first cavity region 221.

In one embodiment, the width of the second cavity region 222 is less than approximately 3 nanometers. The width of the first cavity region 221 is in a range approximately from 4 nanometers to 8 nanometers.

In one embodiment, a ratio of a length of the second cavity region 222 to a length of the first cavity region 221 is in a range approximately from 1:3 to 1:1.

In one embodiment, the isolation structure includes a first isolation layer 208 and a second isolation layer 211 located on a sidewall of the source/drain electrical connection layer 209. A cavity groove exists between the sidewall structure 203 and the first isolation layer 208. The second isolation layer 211 is located on a portion of the sidewall surface of the cavity groove. The second cavity region 222 is located between the second isolation layers 211.

In one embodiment, the source/drain region 201 is located in the substrate 200 at a side of the sidewall structure 203 away from the gate 202.

In the present disclosure, the width of the second cavity region 222 located on the first cavity region 221 is smaller than the width of the first cavity region 221. That is, while the first cavity region 221 retains a larger width, the width of the second cavity region 222 exposed in the subsequent process is made smaller. Accordingly, the possibility of the cavity 223 being damaged in the subsequent process may be reduced, and the integrity of the cavity 223 may be improved. As such, process compatibility may be increased, and device performance may be improved.

The embodiments disclosed in the present disclosure are exemplary only and not limiting the scope of the present disclosure. Various combinations, alternations, modifications, or equivalents to the technical solutions of the disclosed embodiments can be obvious to those skilled in the art and can be included in the present disclosure. Without departing from the spirit of the present disclosure, the technical solutions of the present disclosure may be implemented by other embodiments, and such other embodiments are intended to be encompassed within the scope of the present disclosure.

What is claimed is:

1. A semiconductor structure, comprising:
a substrate, wherein the substrate includes a base, a plurality of channel layers on the base, and an isolation layer between each of the plurality of channel layers;
a gate located on the substrate, wherein the gate spans a top and a portion of sidewalls of the plurality of channel layers;
a sidewall structure located on sidewalls at two sides of the gate;
a source/drain region in the substrate located at two sides of the gate and the sidewall structure;
a source/drain electrical connection layer located on the source/drain region; and
an isolation structure located between the source/drain electrical connection layer and the gate, wherein the isolation structure includes a cavity, and the cavity includes a first cavity region and a second cavity region located on the first cavity region, wherein a width of the second cavity region is smaller than a width of the first cavity region.

2. The semiconductor structure according to claim 1, wherein:
the width of the second cavity region is less than approximately 3 nanometers; and
the width of the first cavity region is in a range approximately from 4 nanometers to 8 nanometers.

3. The semiconductor structure according to claim 1, wherein:
a ratio of a length of the second cavity region to a length of the first cavity region is in a range approximately from 1:3 to 1:1.

4. The semiconductor structure according to claim 1, wherein the isolation structure includes a first isolation layer and a second isolation layer, wherein:
the first isolation layer and the second isolation layer are located on a sidewall of the source/drain electrical connection layer;
a cavity groove exists between the sidewall structure and the first isolation layer;
the second isolation layer is located on a portion of a sidewall surface of the cavity groove; and
the second cavity region is located between the second isolation layers.

5. The semiconductor structure according to claim 1, wherein:
the source/drain region is located in the substrate at a side of the sidewall structure away from the gate.

6. A method of forming a semiconductor structure, comprising:
providing a substrate, wherein the substrate includes a base, a plurality of channel layers on the base, and an isolation layer between each of the plurality of channel layers;
forming a gate on the substrate, a sidewall structure on sidewalls at two sides of the gate, and a source/drain region in the substrate at two sides of the gate and the sidewall structure, wherein the gate spans a top and a portion of sidewalls of the plurality of channel layers;
forming a source/drain electrical connection layer on the source/drain region; and
forming an isolation structure located between the gate and the source/drain electrical connection layer, and a cavity located in the isolation structure, wherein the cavity includes a first cavity region and a second cavity region located on the first cavity region, and a width of the second cavity region is smaller than a width of the first cavity region width.

7. The method according to claim 6, wherein the isolation structure includes:
a first isolation layer and a second isolation layer located on a sidewall of the source/drain electrical connection layer,
wherein:
a cavity groove exists between the sidewall structure and the first isolation layer;
the second isolation layer is located on a portion of a sidewall surface of the cavity groove; and
the second cavity region is located between the second isolation layers.

8. The method according to claim 7, wherein a method of forming the isolation structure includes:
forming a first sacrificial layer on the sidewall structure; and
forming the first isolation layer on the first sacrificial layer,
wherein:
the source/drain electrical connection layer is formed after the first isolation layer is formed.

9. The method according to claim 8, wherein the method of forming the isolation structure further includes:
after forming the source/drain electrical connection layer, etching back the first sacrificial layer to form a second sacrificial layer and an initial cavity groove;
depositing the second isolation layer on a sidewall of the initial cavity groove, and forming the second cavity region between the second isolation layers; and
after forming the second isolation layer, removing the second sacrificial layer to form the first cavity region.

10. The method according to claim 8, wherein:
the first sacrificial layer is made of a material including amorphous silicon.

11. The method according to claim 9, wherein:
a method of removing the second sacrificial layer includes a dry etching process or a wet etching process.

12. The method according to claim 9, wherein:
a method of removing the second sacrificial layer includes a Frontier process.

13. The method according to claim 8, wherein the method of forming the isolation structure further includes:
after forming the source/drain electrical connection layer, removing the first sacrificial layer to form a cavity groove;
depositing an initial second sacrificial layer in the cavity groove;
etching back the initial second sacrificial layer to form a second sacrificial layer, wherein a surface of the second sacrificial layer is lower than a surface of the first sacrificial layer;
depositing the second isolation layer on a sidewall surface of the cavity groove, and forming the second cavity region between the second isolation layers; and
after depositing the second isolation layer, removing the second sacrificial layer to form the first cavity region.

14. The method according to claim 13, wherein:
the second sacrificial layer is made of a carbon-containing material, and/or
a process of removing the second sacrificial layer includes an ashing process.

15. The method according to claim 6, wherein a method of forming the gate, the source/drain region, and the sidewall structure includes:
forming a dummy gate on the substrate;
forming a sidewall structure material layer on a sidewall and a top surface of the dummy gate;
forming a source/drain region in the substrate at two sides of the dummy gate;
forming a first isolation dielectric layer surrounding the source/drain region and the dummy gate on the substrate;
removing the dummy gate to form a gate opening;
depositing an initial gate within the gate opening; and
planarizing the initial gate and the sidewall structure material layer, to form the gate and the sidewall structure on sidewall surfaces at two sides of the gate.

16. The method according to claim 15, wherein a method of forming the source/drain electrical connection layer includes:
forming a source/drain via in the first isolation dielectric layer; and
forming the source/drain electrical connection layer in the source/drain via.

17. The method according to claim 16, after forming the first isolation dielectric layer and before forming the source/drain via, further comprising:
forming a first etch stop layer on the first isolation dielectric layer; and
forming a second isolation dielectric layer on the first etch stop layer,
wherein:
the source/drain via is also located in the second isolation dielectric layer.

18. The method according to claim 7, wherein:
the second isolation layer is made of a material including silicon nitride, silicon oxide, or a combination thereof, and/or
depositing the second isolation layer includes atomic layer deposition.

19. The method according to claim 6, wherein:
the sidewall structure is made of a material including silicon nitride.

20. The method according to claim 6, after forming the cavity, further comprising:
forming a second etch stop layer on a top of the isolation structure, wherein the second etch stop layer enclosing the cavity; and
forming an electrical interconnection layer on the gate and on the source/drain electrical connection layer.
